(19) United States
(12) Patent Application Publication
(10) Pub. No.: US 2017/0104085 A1
(43) Pub. Date: Apr. 13, 2017

(54) SEMICONDUCTOR STRUCTURE AND FORMING METHOD THEREOF

(71) Applicant: ZING SEMICONDUCTOR CORPORATION, Shanghai (CN)

(72) Inventor: DEYUAN XIAO, Shanghai (CN)

(21) Appl. No.: 15/161,472

(22) Filed: May 23, 2016

(30) Foreign Application Priority Data
Oct. 13, 2015 (CN) 201510658749.X

(51) Int. Cl. H01L 29/66; H01L 21/28; H01L 21/225; H01L 29/51; H01L 21/02

(52) U.S. Cl. CPC H01L 29/66636; H01L 29/51; H01L 21/0257; H01L 21/02634; H01L 21/02532; H01L 21/02529; H01L 21/02321; H01L 21/2251; H01L 21/28185; H01L 29/66545

(57) ABSTRACT

This invention provides a semiconductor structure and a forming method thereof. The method for forming the semiconductor structure comprises providing a substrate having a dummy gate; forming source-drain regions in the substrate located in the two sides of the dummy gate, wherein the source-drain region is doped with deuterium; removing the dummy gate; and forming a gate structure having a gate oxide layer in the location of the dummy gate, wherein the deuterium enters the gate oxide layer. In the obtained semiconductor structure, stable covalent bonds can be formed in the gate oxide layer interface because of the deuterium entry, thereby the problems of dangling bonds can be solved. Accordingly, the device recovery against hot carrier effect can be enhanced, and the affections of the device properties caused by hot carrier effect can be reduced.

### BACKGROUND OF THE INVENTION

1. Field of the Invention

The present application relates to a semiconductor manufacturing, and more particularly to a semiconductor structure and a manufacturing method thereof.

2. Description of the Related Art

Recently, the techniques of semiconductor manufacturing are rapidly developed. FIGS. 1 to 6 illustrate the conventional process for manufacturing a metal oxide semiconductor (MOS), which comprises: forming a gate structure 2 on a substrate 1, as shown in FIG. 1; depositing a protective layer 3 on the substrate 1 to cover the gate structure 2; removing a part of the protective layer 3 by reactive ion etching to make the protective layer 3 form slants on two sides of the gate structure 2; further removing a part of the protective layer 3 which is on the substrate 1 to form a side wall 4, as shown in FIG. 2-4; forming a source-drain 5 by epitaxial growth on the substrate 1 and two sides of the gate structure 2, and performing in-situ doping step, as shown in FIG. 5; and performing an annealing process to enter the doped ions into the substrate 1 to form a diffusion layer 6, as shown in FIG. 6.

However, dangling bonds are formed in the semiconductor structure obtained from, but not limited to, the above manufacture process. While dangling bonds occur primarily at surfaces or interfaces in the device, they also are thought to occur at vacancies, micropores, dislocations, and also to be associated with impurities.

Another problem which has arisen in MOS process is the degradation of device performance by hot carrier effects. This is particularly of concern with respect to smaller devices in which proportionally larger voltages are used. When such high voltages are used, channel carriers can be sufficiently energetic to enter an insulating layer and degrade device behavior.

### SUMMARY

The purpose of the present application is to provide a semiconductor structure and its manufacture to reduce or even eliminate the problems caused by dangling bonds and hot carrier effects.

Accordingly, the present application provides a method for forming the semiconductor structure comprising: providing a substrate having a dummy gate; forming source-drain regions in the substrate located in two sides of the dummy gate, wherein the source-drain regions are doped with deuterium; and removing the dummy gate; and forming a gate structure comprising a gate oxide layer in the location of the dummy gate, wherein the deuterium enters the gate oxide layer.

In one embodiment, the step of forming the source-drain regions comprises etching the regions of the substrate located in the two sides of the dummy gate to form grooves; and forming the source-drain regions doped with deuterium in the grooves by homogeneous vapor epitaxy deposition.

In one embodiment, the groove is a Σ-shaped groove or a U-shaped groove, the source-drain region comprises a SiGe epitaxial layer or a SiC epitaxial layer, and the deuterium is doped to the SiGe epitaxial layer or the SiC epitaxial layer.

In one embodiment, the homogeneous vapor epitaxy deposition comprises applying a first source gas and a second source gas to form the deuterium-doped source-drain region.

In one embodiment, the first source gas is 50%-90% by volume.

In one embodiment, the first source gas is deuterium or a mixture of deuterium and hydrogen. The mixture contains 2 vol %-98 vol % of deuterium.

In one embodiment, the second source gas is selected from SiH₄, Si₂H₆, SiH₂Cl₂, SiHCl₃, SiCl₄, Si(CH₃)₄, GeH₄, C₃H₈ and CH₄, which can be used alone or in combination.

In one embodiment, the homogeneous vapor epitaxy deposition is performed under 800° C.-1100° C. for 10-2000 minutes.

The present application also provides a semiconductor structure formed by the above method, comprising: a substrate; a gate structure formed on the substrate, wherein the gate structure comprises a gate oxide layer doped with deuterium; source-drain regions formed in the substrate located in the two sides of the gate structure, wherein the source-drain regions are doped with deuterium

Compared to prior art, the present application provides a method for forming the semiconductor structure comprising providing a substrate comprising a dummy gate; forming source-drain regions in the substrate located in the two sides of the dummy gate, wherein the source-drain region is doped with deuterium; removing the dummy gate; and forming a gate structure having a gate oxide layer in the location of the dummy gate, wherein the deuterium enters the gate oxide layer. In the obtained semiconductor structure, stable covalent bonds can be formed in the gate oxide layer interface because of the deuterium entry, thereby the problems of dangling bonds can be solved. Accordingly, the device recovery against hot carrier effect can be enhanced, and the affections of the device properties caused by hot carrier effect can be reduced.

### BRIEF DESCRIPTION OF THE DRAWINGS

FIGS. 1 to 6 illustrate the conventional semiconductor structures during the manufacturing process;

FIG. 7 illustrates the process for forming the semiconductor structure of the present application; and

FIGS. 8 to 11 illustrate the semiconductor structures of the present application during the manufacturing process.

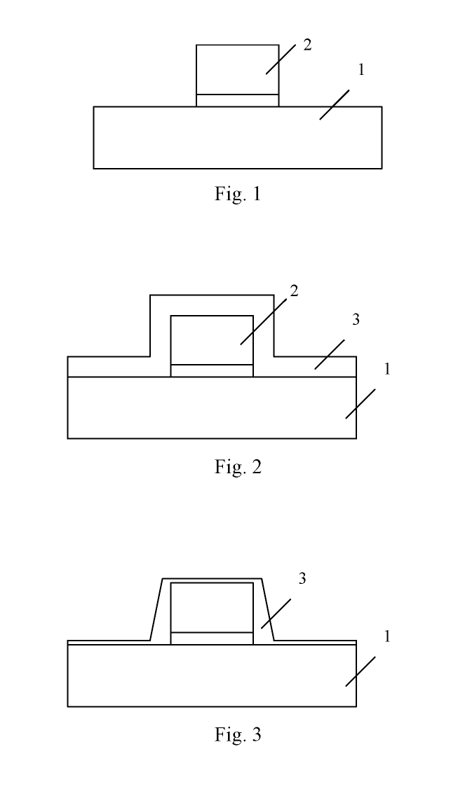

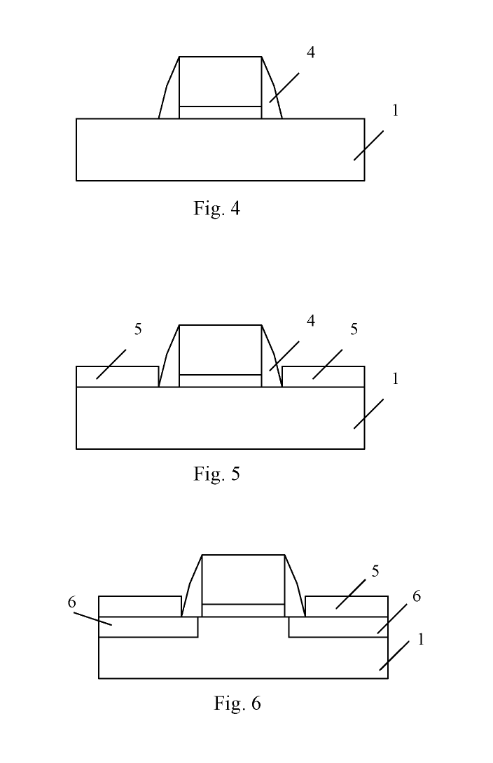

### DETAILED DESCRIPTION OF THE EMBODIMENTS

Although the following with reference to the accompanying drawings of the method of the present invention is further described in more detail, there is shown a preferred embodiment of the present invention. A person having ordinary skills in the art may modify the invention described herein while still achieving the advantageous effects of the present invention. Thus, these embodiments should be understood as broad teaching one skilled in the art, and not as a limitation of the present invention.

For purpose of clarity, not all features of an actual embodiment are described. It may not describe the well-known functions as well as structures in detail to avoid confusion caused by unnecessary details. It should be considered that, in the developments of any actual embodiment, a large number of practice details must be made to achieve the specific goals of the developer, for example, according to the requirements or the constraints of the system or the commercials, one embodiment is changed to another. In addition, it should be considered that such a development effort might be complex and time-consuming, but for a person having ordinary skills in the art is merely routine work.

In the following paragraphs, the accompanying drawings are referred to describe the present invention more specifically by way of example. The advantages and the features of the present invention are more apparent according to the following description and claims. It should be noted that the drawings are in a simplified form with non-precise ratio for the purpose of assistance to conveniently and clearly explain to an embodiment of the present invention.

The present application provides a semiconductor structure and a method for forming thereof. The method comprises providing a substrate having a dummy gate; forming source-drain regions in the substrate located in two sides of the dummy gate, wherein the source-drain regions are doped with deuterium; and removing the dummy gate; and forming a gate structure comprising a gate oxide layer in the location of the dummy gate, wherein the deuterium enters the gate oxide layer. Accordingly, deuterium incorporates into the gate oxide layer to enhance device properties.

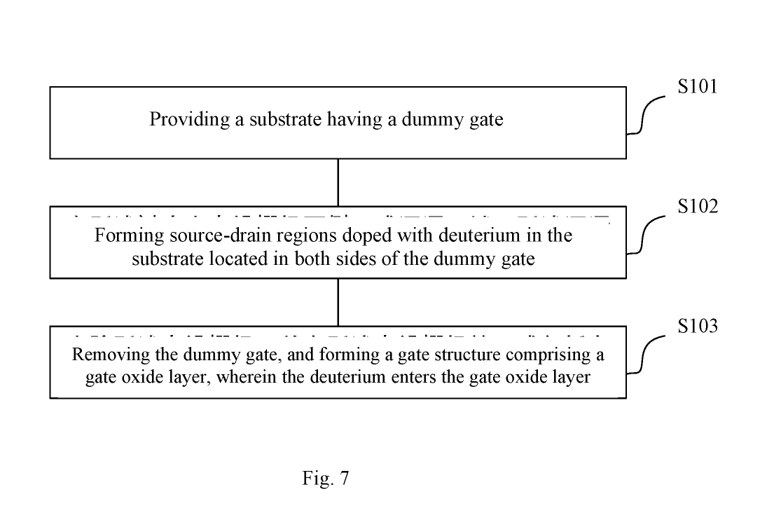

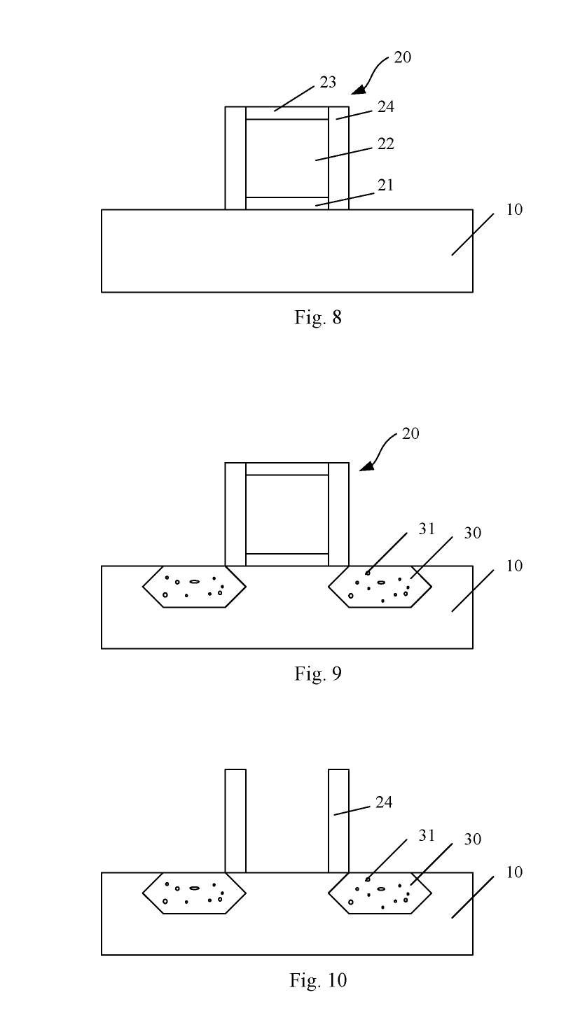

Referring to FIGS. 7-11, the semiconductor structure and the manufacturing process are detail described. FIG. 7 illustrates the process for forming the semiconductor structure of the present application; and FIGS. 8 to 11 illustrate the semiconductor structures of the present application during the manufacturing process.

Referring to FIG. 7, the process comprises the following steps.

First, also referring to FIG. 8, the step S101 is carried out to provide a substrate 10 having a dummy gate 20; the substrate 10 can be non-doped monocrystalline silicon, impurity-doped monocrystalline silicon and the like. For example, in the present embodiment, the substrate 10 is monocrystalline silicon. A buried layer (not shown in the figure) may be formed in the substrate 10. In addition, for P-type metal oxide semiconductor (PMOS), the N-well (not shown in the figure) may be formed in the substrate 10, and the low-dose boron implantation to the N-well may be performed once or multiple times to adjust threshold voltage (Vth) of the PMOS. The dummy gate 20 may include, such as, a dummy gate oxide layer 21, a polycrystalline silicon block 22, a mask layer 23, and a side-wall 24. The conventional gate last process can be referred and selected to prepare the dummy gate 20.

After completing the step S101, the routine steps such as washing the substrate and the like may be applied. The routine steps well known in the art are not described herein.

Then, also referring to FIG. 9, the step S102 is carried out to form the source-drain regions 30 in the substrate 10 in both side of the dummy gate 20, wherein the source-drain regions 30 are doped with deuterium 31. In particular, the step S102 comprises etching the substrate 10 in the area in the both sides of the dummy gate 20 to form grooves. In one embodiment, the etching such as dry etching may be applied to form a Σ-shaped groove or a U-shaped groove. For example, Σ-shaped grooves are formed in the present embodiment. After the groove formation, the source-drain regions 30 doped with deuterium 31 are formed in the grooves by homogeneous vapor phase epitaxial deposition. The source-drain regions 30 may comprise a SiGe epitaxial layer or a SiC epitaxial layer to improve the device properties. The deuterium 31 is doped to the SiGe epitaxial layer or the SiC epitaxial layer. The homogeneous vapor epitaxy deposition comprises applying a first source gas and a second source gas to form the deuterium-doped source-drain regions. In a preferred embodiment, the first source gas is 50%-90% by volume. The first source gas is deuterium or a mixture of deuterium and hydrogen, wherein the mixture contains 2 vol %-98 vol % of deuterium. The second source gas is selected from SiH₄, Si₂H₆, SiH₂Cl₂, SiHCl₃, SiCl₄, Si(CH₃)₄, GeH₄, C₃H₈ and CH₄, which can be used alone or in combination. Preferably, the homogeneous vapor epitaxy deposition is performed under 800° C.-1100° C. for 10-2000 minutes.

Gas amount, reaction temperature and reaction time can be adjusted depending on requirements of practical necessity to obtain the desired source-drain regions 30.

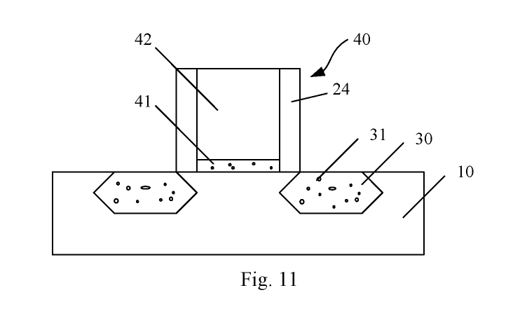

Then, also referring to FIG. 10 and FIG. 11, the step S103 is carried out to remove the dummy gate and form a gate structure 40 comprising a gate oxide layer 41 in the location of the dummy gate, wherein the deuterium 31 enters the gate oxide layer 41. In one embodiment, the dummy gate oxide layer 21, the polycrystalline silicon block 22 and the mask layer 23 are removed. A photoresist may be used to cover all areas except the dummy gate 20, and the dummy gate 20 is removed by the wet etching process. After removal of the dummy gate oxide layer 21, the polycrystalline silicon block 22 and the mask layer 23, the gate oxide layer 41 and the gate block 42 thereon can be formed under 500° C.-1150° C. to obtain the gate structure 40. In one embodiment, the gate block 42 comprises such as a high K dielectric layer, a metal gate and the like. During the formation of the gate oxide layer 41, the deuterium 31 diffuses from the epitaxy layer of the source-drain regions 30 to the gate oxide layer 41 because of high temperature, then aggregate at the interface. Accordingly, the stable Si-D covalent bonds are formed at the interface.

Referring to FIG. 11, a semiconductor structure is obtained according to the method of the present application, which comprises: the substrate 10; the gate structure 40 formed on the substrate 10, wherein the gate structure 40 comprises the gate oxide layer 41 doped with the deuterium 31; the source-drain regions 30 formed in the substrate 10 located in both sides of the gate structure 40, wherein the source-drain regions 30 are doped with the deuterium 31.

In the obtained semiconductor structure, stable covalent bonds are formed at the interface of the gate oxide layer 41, thereby the problems of dangling bonds can be solved. Further, because of existence of the dangling bonds, the device recovery against hot carrier effect can be enhanced, and the affections of the device properties caused by hot carrier effect can be reduced.

Realizations of the above method have been described in the context of particular embodiments. These embodiments are meant to be illustrative and not limiting. Many variations, modifications, additions, and improvements are possible. These and other variations, modifications, additions, and improvements may fall within the scope of the invention as defined in the claims that follow.

What is claimed is:

1. A method for forming a semiconductor structure comprising:
providing a substrate having a dummy gate;
forming source-drain regions in the substrate located in the two sides of the dummy gate, wherein the source-drain region is doped with deuterium; and
removing the dummy gate; and forming a gate structure comprising a gate oxide layer in the location of the dummy gate, wherein the deuterium enters the gate oxide layer.

2. The method of claim 1, wherein the step of forming source-drain regions comprises etching the regions of the substrate located in the two sides of the dummy gate to form grooves; and forming the source-drain regions doped with deuterium in the grooves by homogeneous vapor epitaxy deposition.

3. The method of claim 2, wherein the groove is a Σ-shaped groove or a U-shaped groove, the source-drain region comprises a SiGe epitaxial layer or a SiC epitaxial layer, and the deuterium is doped to the SiGe epitaxial layer or the SiC epitaxial layer.

4. The method of claim 2, wherein the homogeneous vapor epitaxy deposition comprises applying a first source gas and a second source gas to form the deuterium-doped source-drain region.

5. The method of claim 4, wherein the first source gas is 50%-90% by volume.

6. The method of claim 5, wherein the first source gas is deuterium or a mixture of deuterium and hydrogen with 2 vol %-98 vol % of deuterium.

7. The method of claim 4, wherein the second source gas is selected from a group consisting of SiH₄, Si₂H₆, SiH₂Cl₂, SiHCl₃, SiCl₄, Si(CH₃)₄, GeH₄, C₃H₈ and CH₄.

8. The method of claim 2, wherein the homogeneous vapor epitaxy deposition is performed under 800° C.-1100° C. for 10-2000 minutes.

9. A semiconductor structure formed by a method of claim 1, comprising:
a substrate;
a gate structure formed on the substrate, wherein the gate structure comprises a gate oxide layer doped with deuterium;
source-drain regions formed in the substrate located in the two sides of the gate structure, wherein the source-drain regions are doped with deuterium.
